(19) United States
(12) Patent Application Publication
(10) Pub. No.: US 2025/0259940 A1
(43) Pub. Date: Aug. 14, 2025

(54) PARALLEL LINES FORMED BY ISOLATION CUT

(71) Applicant: INTERNATIONAL BUSINESS MACHINES CORPORATION, ARMONK, NY (US)

(72) Inventors: Lawrence A. Clevenger, Saratoga Springs, NY (US); Albert M. Chu, Nashua, NH (US); Carl Radens, LaGrangeville, NY (US); Geng Han, Niskayuna, NY (US); Brent A. Anderson, Jericho, VT (US); Ruilong Xie, Niskayuna, NY (US); Mahender Kumar, Clifton Park, NY (US); Xiaoming Yang, Clifton Park, NY (US)

(21) Appl. No.: 18/440,907

(22) Filed: Feb. 13, 2024

(51) Int. Cl. H01L 23/544; H01L 21/304

(52) U.S. Cl. CPC H01L 23/544; H01L 21/3043; H01L 2223/5446

(57) ABSTRACT

A semiconductor device includes a first metal line, and a second metal line adjacent and coplanar to the first metal line. The first metal line and the second metal line have a common patterning level, and the first metal line and the second metal line are separated by a cut region parallel to a length of the first metal line and the second metal line.

### BACKGROUND

### Technical Field

The present disclosure generally relates to transistors, and more particularly, to forming parallel lines by an isolation cut along the length of the line and methods of creation thereof.

### Description of the Related Art

Metal cuts are often used to electrically isolate different regions or components on a semiconductor chip to prevent unintended electrical connections and cross-talk between adjacent metal traces. In multi-layered interconnect structures, metal cut is the process of cutting one metal shape into two metal shapes. Such metal shapes would allow vertical connections (vias) between different metal layers to enable signals to pass from one metal layer to another. Further, the metal shapes can be used to create contacts or pads that provide electrical connections between metal layers and other structures, such as transistors or capacitors, and can also help in routing signals across the chip's surface. These can be used to define pathways for signal propagation between different components.

### SUMMARY

According to an embodiment, a semiconductor device has a first metal line, and a second metal line adjacent to the first metal line. The first metal line and the second metal line have a common patterning layer. The first metal line and the second metal line are separated by a cut region parallel to a length of the first metal line and the second metal line.

In some embodiments, which can be combined with previous embodiment, the cut region parallel to the first metal line and the second metal line form two-line features from a same mask.

In some embodiments, which can be combined with one or more previous embodiments, the cut region isolates the first and second metal lines.

In some embodiments, which can be combined with one or more previous embodiments, the first cut region is parallel to the first metal line.

In some embodiments, which can be combined with one or more previous embodiments, the cut region isolates one or more line segments between the first and second metal lines.

In some embodiments, which can be combined with one or more previous embodiments, a width of the cut region is smaller than a width of the first metal line prior to being cut by the cut region.

In some embodiments, which can be combined with one or more previous embodiments, the cut region has a rectangular shape.

According to another embodiment, a method of formation of a semiconductor device includes forming a first metal line, forming a second metal line adjacent to the first metal line, and forming a cut region to separate the first metal line and the second metal line. The cut region is formed parallel to a length of the first metal line and the second metal line.

In some embodiments, which can be combined with the previous embodiment, the first metal line and the second metal line have a common patterning layer.

In some embodiments, which can be combined with one or more previous embodiments, the method includes isolating, by the cut region, the first and second metal lines.

In some embodiments, which can be combined with one or more previous embodiments, the method includes isolating, by the cut region, one or more line segments between the first and second metal lines.

In some embodiments, which can be combined with one or more previous embodiments, the method includes isolating, by the cut region, the first and second metal lines by forming an L-shaped cut region.

In some embodiments, which can be combined with one or more previous embodiments, a length of the first metal line is larger than a length of the second metal line.

In some embodiments, which can be combined with one or more previous embodiments, a width of the cut region is smaller than a width of a first metal line prior to being cut by the cut region.

According to yet another embodiment, a semiconductor device includes a first metal line including a first part and a second part, and a second metal line. The second metal line changes level to extend around the second part of the first metal line, and the first part is separated from the second part by a first cut region.

In some embodiments, which can be combined with the previous embodiment, the first cut region is parallel with the first part and the second part of the first metal line.

In some embodiments, which can be combined with one or more previous embodiments, the first cut region is located between the first part and the second part.

In some embodiments, which can be combined with one or more previous embodiments, the semiconductor device includes a second cut region in the second metal line which is perpendicular to the first cut region.

In some embodiments, which can be combined with one or more previous embodiments, the second first and second cut regions have a rectangular shape.

In some embodiments, which can be combined with one or more previous embodiments, at least one of the first and second cut regions has an L-shape.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate conventional metal cuts.

FIG. 2A illustrates a semiconductor device with a cut mask, in accordance with some embodiments.

FIG. 2B illustrates a semiconductor device with a cut region, in accordance with some embodiments.

FIG. 3 illustrates a semiconductor device with two cut regions, in accordance with some embodiments.

FIG. 4A illustrates a first metal line, in accordance with some embodiments.

FIG. 4B illustrates a first metal line and a second metal line, in accordance with some embodiments.

FIG. 4C illustrates the first and second metal lines after forming cut masks, in accordance with some embodiments.

FIG. 4D illustrates the first and second metal lines after forming the cut regions, in accordance with some embodiments.

FIG. 5 illustrates an exemplary memory cell, in accordance with some embodiments.

FIG. 6 illustrates block diagrams of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and similarly, a second element could be termed a first element without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature, and their shapes do not necessarily illustrate the actual shape of a region of a device and do not limit the scope.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

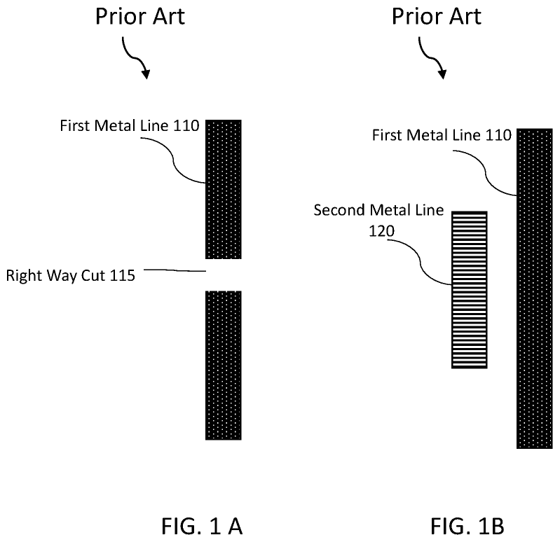

As semiconductor technology advances and device dimensions shrink, the precision and control of metal cuts become more critical to maintain signal integrity, minimize resistance, and ensure reliable electrical connections. Metal cuts in semiconductors are openings or trenches created in metal layers during the balk end of line (BEOL) processing. They serve various purposes, including isolation, interlayer connections, contact formation, and signal routing. The fabrication of metal cuts can involve photolithography and etching processes, contributing to the creation of intricate interconnect networks in integrated circuits. FIGS. 1A-1B illustrate conventional methods to perform the metal cuts. FIG. 1A depicts a first metal line 110 with a right way cut 115. A right way cut can refer to a cut that is perpendicular to the length of the metal line. Similarly, a wrong way cut can refer to a cut that is parallel to the length of the metal line. FIG. 1B depicts a first metal line 110 and a second metal line 120 that are patterned by two separate patterning masks.

Achieving uniform etching across the entire wafer surface is essential for consistent metal cut dimensions. Non-uniform etching can lead to variations in the performance of the integrated circuits. Although planarization steps, such as Chemical Mechanical Polishing (CMP), can be performed to ensure a flat surface before further processing, it is difficult to form uniform metal cuts while keeping up with the ever-shrinking size of the semiconductor devices. If issues are identified after metal cuts have been made, rework or repair options may be limited, as altering metal cuts without affecting neighboring structures can be challenging. Thus, forming precise metal cuts while narrowing the separation distance between metal lines is a salient consideration.

The concepts herein relate to minimizing the separation distance between metal lines while the metal cuts are formed. Disclosed metal cuts can facilitate the creating of complex interconnect structures in a semiconductor device.

Accordingly, the teachings herein provide methods and systems of metal cut formation in a semiconductor device. The techniques described herein may be implemented in a number of ways. Example implementations are provided below with reference to the following figures.

Example Semiconductor Device with Metal Cuts Structure

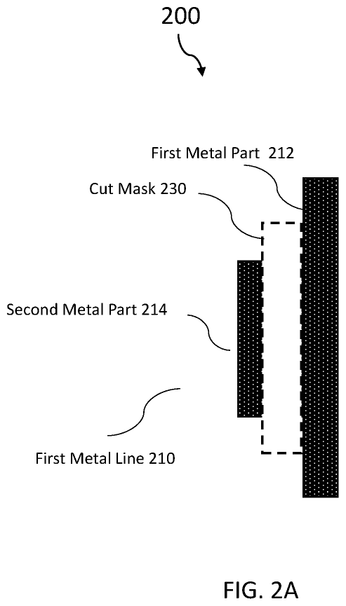

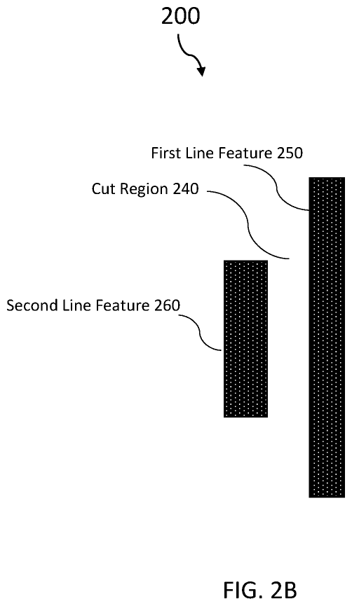

Reference now is made to FIGS. 2A-2B, which are simplified top views of a semiconductor device 200, consistent with some illustrative embodiments. Referring to FIG. 2A now, the disclosed semiconductor device 200 can include a first metal line 210, and a cut mask 230. The cut mask 230 can be extended parallel and along the length of the first and divide the first metal line into a first metal part 212 and a second metal part 214.

Conventional semiconductor devices may include a first meal line and a second metal line at two different patterning levels. However, in one aspect, the semiconductor device 200 includes the first metal part 212 and second metal part 214 with a common patterning level, i.e., common patterning layer, and be separated by the cut mask 230.

FIG. 2B illustrates the semiconductor device 200 after the cut mask is removed. In several embodiments, the cut mask is removed to form a cut region 240, which separates the first metal part and the second metal part. As a result of forming the cut region 240 along the first metal line, two line features from the same color mask can be formed. A person skilled in the art would understand that, in the context of semiconductors, “same color” means the same patterning level, i.e., the same layer. Similarly, elements with “different colors” means that such elements are on different layers. In an embodiment, the cut region 240 forms a first line feature 250, which is formed from the first metal part, and a second line feature 260, which is formed from the second metal part. Further, since the first metal part and the second metal part have a common patterning level, i.e., share the same color, the first line feature 250, and the second line feature 260 also have a common patterning level, i.e., share the same color.

In some embodiments, the cut region 240 isolates the first line feature 250 and the second line feature 260. The first line feature 250, and the second line feature 260 can have the same width. In an embodiment, the length of the cut region 240, which can have a rectangular shape, is 3 times longer than the width of the first line feature 250 and the second line feature 260.

Additionally, or in the alternative, the length of the first line feature 250 can be larger than that of the second line feature 260. In some embodiments, prior to being cut by the cut region 240, the width of the cut region 240 is smaller than the width of the first line feature 260. In other words, the separation distance, created by the cut region 240, can be larger than the width of each of the first line feature 250 and the second line feature 260. The cut region 240 can isolate one or more line segments between the first line feature 250 and the second line feature 260.

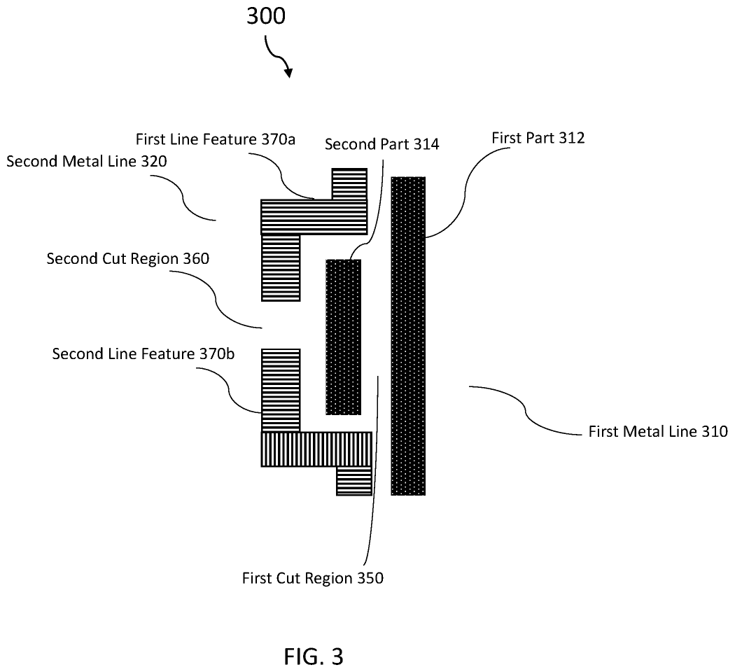

FIG. 3 illustrates a semiconductor device 300, in accordance with some embodiments. The semiconductor device 300 can include a first metal line 310 and a second metal line 320. The first metal line 310 includes a first part 312 and a second part 314 extending parallel to each other. In the example of FIG. 3, the first part 312 and the second part 314 can be separated by a first cut region 350. The first cut region 350 can be extended parallel to the first part 312 and the second part 314 of the first metal line 310. In an embodiment, the second metal line 320 is extended parallel to the first metal line 310, i.e., the first part 312 and the second part 314.

In an embodiment, while the first cut region 350 is parallel to the first and second parts 312 and 314, the second cut region 360 is perpendicular to the first and second metal lines 310 and 320, the first and second parts 312 and 314, and the first cut region 350. The first and second cut regions 350 and 360 isolate one or more line segments between the first and second metal lines 310 and 320. For instance, as illustrated in FIG. 3, the first cut region 350 can isolate the first part 312 and the second part 314 of the first metal line 310. Similarly, the second cut region 360 isolates the upper portion, i.e., the first line feature 370a, and the lower portion, i.e., the second line feature 370b, of the second metal line 320. In such embodiments, the second cut region 360 forms the upper and lower sections, i.e., the first and second line features 370a and 370b, by cutting the second metal line 320.

In several embodiments, the first part 312 and the second part 314 have a second common patterning level, i.e., share the second color. Similarly, the first line feature 370a and the second line feature 370b have a first common patterning level, i.e., share the first color. Since the first metal line 310 and the second metal line 320 are on different patterning levels, i.e., have different colors, then the first line feature 370a and the second line feature 370b have a different patterning level that the first part 312 and the second part 314. That is, the first and second colors are different.

In some embodiments, the first cut region 350 isolates the first and second parts 312 and 314. The first part 312, and the second part 314 can have the same width. The length of the first cut region 350, which can have a rectangular shape, can be larger than the width of the first and second parts 312 and 314. The first cut region can be parallel to one of the remaining metal segment after the metal cut process. For example, the first cut region 350 is parallel to the first part 312.

Additionally, or in the alternative, the length of the first part 312 can be larger than the length of the second part 314. In some embodiments, prior to being cut by the first cut region 350, the width of the first cut region 350 can be smaller than the width of the first part 312. In other words, the separation distance, created by the first cut region 350, can be larger than the width of each of the first and second parts 312 and 314.

In some embodiments, the second cut region 360 can isolate the first and second line features 370a and 370b. The first line feature 370a and the second line feature 370b can have the same width. At least one of the first and second cut regions can have a different shape than a rectangular shape. For instance, one or more of the first and second cut regions 350 and 360 can have an L-shape.

Example Processes for a Semiconductor Device with Metal Cuts Structures

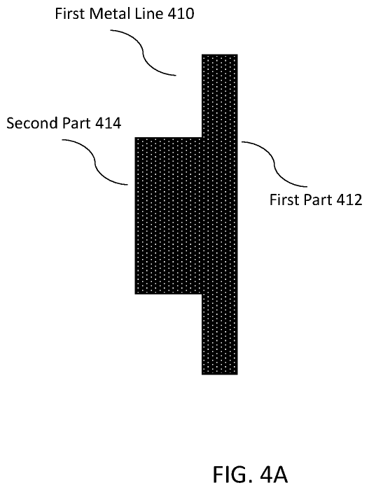

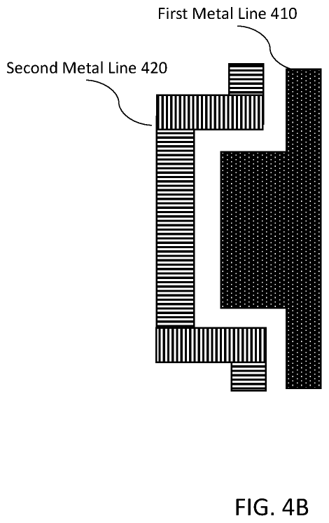

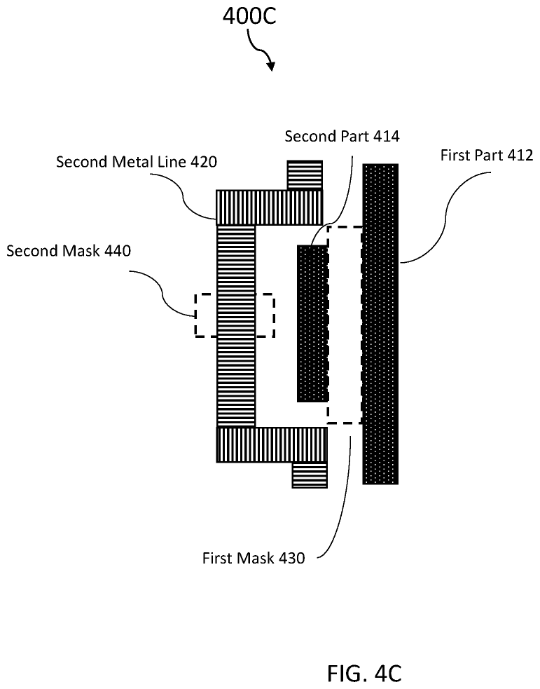

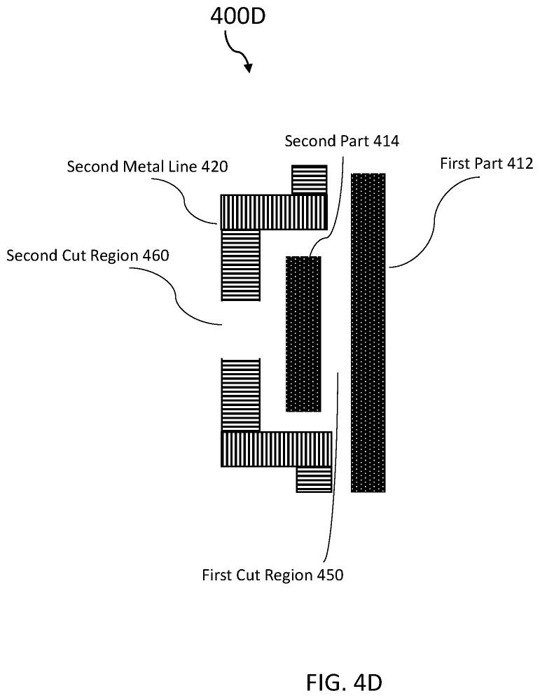

With the foregoing description of an example semiconductor device, it may be helpful to discuss an example process of manufacturing the same. To that end, FIGS. 4A-4D illustrate various steps in the manufacture of a semiconductor device, consistent with illustrative embodiments. It is worth mentioning that the semiconductor device depicted in FIG. 3 can be the same as the semiconductor device depicted in FIGS. 4A-4D.

Referring to FIG. 4A now, a first metal line is illustrated, in accordance with some embodiments. In some embodiments, the first metal line 410 can include a first part 412, and a second part 414. The length of the first part 412 can be larger than the length of the second part 414.

FIG. 4B illustrates a first metal line and a second metal line, in accordance with some embodiments. In some embodiments, the second metal line 420 is formed adjacent to the first metal line 410. The second metal line 420 can be extended parallel to the first metal line 410, i.e., the first portion and the second portion.

In several embodiments, the first metal line 410 and the second metal line 420 are on different patterning levels, i.e., have different colors. The first and second metal lines can have a substantially equal length. The upper and lower ends of the second metal line 420 can extend towards the first metal line 410 without being in contact with the first metal line 410. As shown in FIG. 4B, the second metal line 420 is extended around the first metal line 410.

FIG. 4C illustrates a semiconductor device 400C after a first and second masks are formed, in accordance with some embodiments. In some embodiments, a first mask 430 is formed over the first metal line. The first mask 430 can be formed parallel to the first and second parts 412 and 414 such that the first and second parts 412 and 414 are not in direct contact with each other. In some embodiments, the second mask 440 is formed over the second metal line. The second mask 440 can be formed perpendicular to the second metal line 420, such that the second metal line 420 can be divided into two portions.

FIG. 4D illustrates a semiconductor device 400D after a first and second cut regions are formed, in accordance with some embodiments. In some embodiments, a first cut region 450 is formed over the first metal line by removing the first mask. The first cut region 450 can be formed parallel to the first and second parts 412 and 414 such that the first and second parts 412 and 414 are not in direct contact with each other. In some embodiments, the second cut region 460 is formed over the second metal line 420. The second cut region 460 can be formed perpendicular to the second metal line 420, such that the second metal line 420 can be divided into two portions.

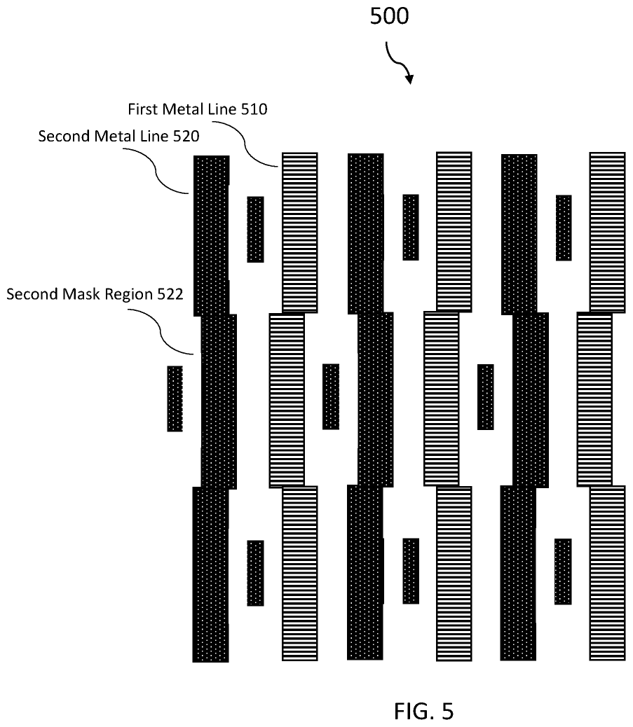

FIG. 5 illustrates a semiconductor device 500, in accordance with some embodiments. In some embodiments, the semiconductor device 500 can be a Static Random-Access Memory (SRAM) bitcell array with M2 WordLine, which is a type of volatile semiconductor memory. The semiconductor device 500 can provide high-speed access to stored data and be used as cache memory, as well as for various memory storage applications. The semiconductor device 500 can include multiple parallel worldlines extended vertically. As noted above, a person skilled in the art would understand that, in the context of semiconductors, “same color” means the same patterning level, i.e., the same level. Similarly, elements with “different colors” means that such elements are on different patterning levels. Conventional semiconductors can use three different colors of metal layers with orthogonal cuts, due to the reduction in bitcell area and the tight M2 lines. However, in some embodiments, the semiconductor device 500 includes 2-color metal lines, i.e., the first metal line 510 and the second metal line 520, in both parallel and orthogonal directions, i.e., perpendicular direction. Similar to FIG. 4C, the second cut region 522 can separate, i.e., isolate, the two parts of the second metal line 520.

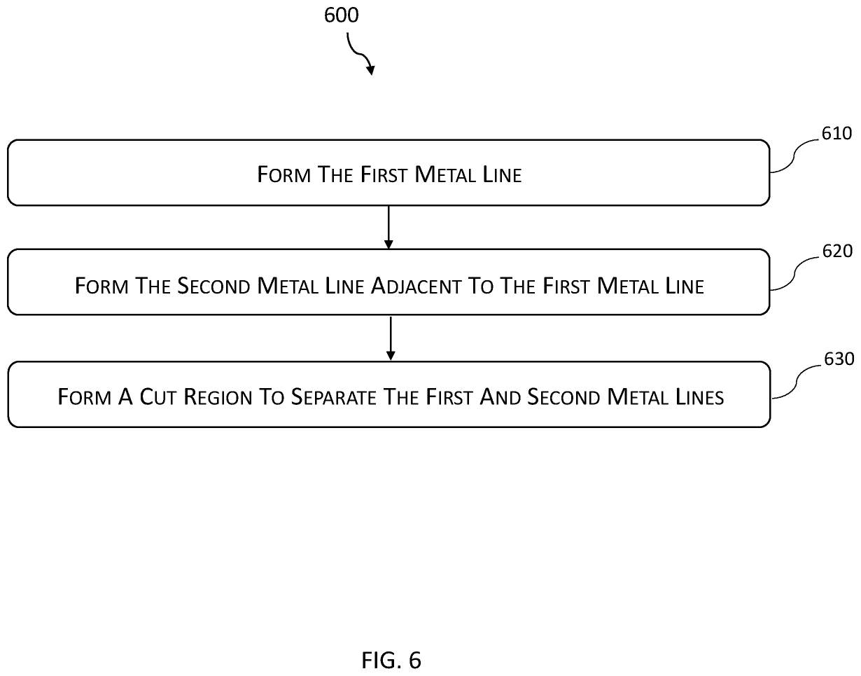

FIG. 6 illustrates a block diagram of a method 600 for forming a semiconductor device, in accordance with some embodiments. Method 600 can begin when a first metal line is formed, as shown by block 610.

In an embodiment, method 600 proceeds when a second metal line is formed, as shown by block 620. The second metal line can be formed adjacent to the first metal line and can be coplanar to the first metal line.

Method 600 continues when a cut region is formed, as shown by block 630. The cut region can separate the first metal line from the second metal line.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first metal line; and
a second metal line adjacent and coplanar to the first metal line, wherein:
the first metal line and the second metal line have a common patterning level; and
the first metal line and the second metal line are separated by a cut region parallel to a length of the first metal line and the second metal line.

2. The semiconductor device of claim 1, wherein the cut region along the first metal line and the second metal line form two line features from a same mask.

3. The semiconductor device of claim 1, wherein the cut region isolates the first and second metal lines.

4. The semiconductor device of claim 1, wherein the cut region is parallel to the first metal line.

5. The semiconductor device of claim 1, wherein the cut region isolates one or more line segments between the first and second metal lines.

6. The semiconductor device of claim 1, wherein a width of the cut region is smaller than a width of the first metal line prior to being cut by the cut region.

7. The semiconductor device of claim 1, wherein the cut region has a rectangular shape.

8. A method for fabricating a semiconductor device, the method comprising:
forming a first metal line;
forming a second metal line adjacent and coplanar to the first metal line; and
forming a cut region to separate the first metal line and the second metal line, wherein the cut region is formed parallel to a length of the first metal line and the second metal line.

9. The method of claim 8, wherein the first metal line and the second metal line have a common patterning layer.

10. The method of claim 8, further comprising isolating the first and second metal lines, by the cut region.

11. The method of claim 8, further comprising isolating one or more line segments between the first and second metal lines, by the cut region.

12. The method of claim 8, further comprising isolating the first and second metal lines, by the cut region, by forming an L shape.

13. The method of claim 8, wherein a length of the first metal line is longer than a length of the second metal line.

14. The method of claim 8, wherein a width of the cut region is smaller than a width of the first metal line prior to being cut by the cut region.

15. A semiconductor device, comprising:
a first metal line, the first metal line comprising a first part and a second part, wherein the first part is separated from the second part by a first cut region; and
a second metal line, wherein the second metal line changes level to extend around the second part of the first metal line.

16. The semiconductor device of claim 15, wherein the first cut region is parallel with the first part and the second part of the first metal line.

17. The semiconductor device of claim 15, wherein the first cut region is located between the first part and the second part.

18. The semiconductor device of claim 15, further comprising a second cut region in the second metal line, wherein the second cut region is perpendicular to the first cut region.

19. The semiconductor device of claim 18, wherein the first cut region and the second cut region have a rectangular shape.

20. The semiconductor device of claim 15, wherein at least one of the first cut region or the second cut region has an L-shape.
